(19) United States
(12) Patent Application Publication
(10) Pub. No.: US 2010/0116326 A1
(43) Pub. Date: May 13, 2010

(54) Hybrid Solar Cells with 3-Dimensional Hyperbranched Nanocrystals

(75) Inventors: Ilan Gur, San Francisco, CA (US); Neil Fromer, Pasadena, CA (US); A. Paul Alivisatos, Oakland, CA (US)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: The Regents of the University of California, Oakland, CA (US)

(21) Appl. No.: 12/446,209

(22) PCT Filed: Oct. 18, 2007
(86) PCT No.: PCT/US07/81813

§ 371 Date: Sep. 24, 2009

Related U.S. Application Data
(60) Provisional application No. 60/862,135, filed on Oct. 19, 2006.

(51) Int. Cl. H01L 31/042; H01B 1/00; H01B 1/02

(52) U.S. Cl. 136/252; 252/500; 252/512

(57) ABSTRACT

A hyperbranched semiconductor nanocrystal particle, which includes a first arm, where the first arm has an intermediate portion and opposing terminal portions, and a second arm, extending from the intermediate portion of the first arm.

### CROSS-REFERENCES TO RELATED APPLICATIONS

This application claims priority to U.S. Provisional Application No. 60/862,135, filed Oct. 19, 2006, which is herein incorporated by reference in its entirety for all purposes.

### STATEMENT AS TO RIGHTS TO INVENTIONS MADE UNDER FEDERALLY SPONSORED RESEARCH OR DEVELOPMENT

The invention described and claimed herein was made in part utilizing funds supplied by the U.S. Department of Energy under Contract No. DE-AC02-05CH11231 and in part utilizing funds supplied by the DARPA-VHESC project. The government has certain rights in this invention.

### BACKGROUND OF THE INVENTION

Early research in organic photovoltaic systems demonstrated clearly that excitons in conjugated polymers are best harvested via charge separation across a type II donor-acceptor (D-A) heterojunction with another material. A variety of species, such as small organic molecules, other polymers, C₆₀, and inorganic semiconductor nanocrystals have been used successfully with conjugated polymers in D-A nanocomposite solar cells. The short exciton diffusion lengths of most conjugated polymers suggest that the optimal architecture for these devices is a nanoscale composite active layer with a blended or bulk heterojunction. The morphology of such a nanocomposite layer can dictate the performance of the cell. It is useful to limit polymer domain dimensions to twice the exciton diffusion length, typically 5-20 nm, for efficient exciton separation. In addition, it is useful for both the donor and acceptor phases to form high-quality percolation networks spanning the thickness of the device to ensure efficient carrier collection at the electrodes. Governed by these morphology desires, processing of nanocomposite D-A heterojunctions is extremely difficult and has attracted much interest.

Many hybrid nanocrystal-polymer blends are prepared currently by spin-casting a co-solution of nanocrystals and polymer from a two-solvent system. This process is far from optimal, as dispersion in the solvent relies on the metastable solubility of the blend components. The resulting spin-cast film is a disordered blend whose specific morphology may vary based on differences in nanocrystal synthesis conditions and cleaning procedures. In addition, small variations in the solvent composition can cause large-scale aggregation of either blend component, with detrimental effects on device performance. Nanorods and small, branched nanoparticles have enhanced the performance of polymer-nanocrystal solar cells in recent years, with their improved electron transport vis-à-vis quantum dots. However, electron extraction is still limited by hopping through a percolation network of particles. Moreover, the creation of percolation networks in these cells remains highly sensitive to solubility in the blend solutions; morphological defects and deficiencies are common. Attempts to prescribe the morphology of hybrid blends using ordered templates may be promising, but these designs require complex fabrication methods and have yet to produce significant results. What is needed is an efficient hybrid solar cell whose blend morphology is insensitive to solubility and processing variations.

The aforementioned need is satisfied by the embodiments of the present invention which include efficient hybrid solar cells whose blend morphology is controlled by the 3-D structure of a hyperbranched nanocrystal phase. The cells combine the simple processing and easy fabrication of nanocrystal blend cells with the ordered morphology and transport network of template-based systems.

### BRIEF SUMMARY OF THE INVENTION

In one embodiment, the present invention provides a hyperbranched semiconductor nanocrystal particle comprising a first arm, wherein the first arm comprises an intermediate portion and opposing terminal portions; and a second arm, extending from the intermediate portion of the first arm.

In a second embodiment, the present invention provides a hyperbranched semiconductor nanocrystal particle comprising at least five primary arms extending from a core, wherein each primary arm comprises an intermediate portion and opposing terminal portions, wherein the core comprises one terminal portion of each of the primary arms.

In a third embodiment, the present invention provides a method of preparing a hyperbranched semiconductor nanocrystal particle of the present invention, comprising contacting a first semiconductor precursor, a second semiconductor precursor and a surfactant mixture comprising a bifunctional surfactant, thereby preparing a hyperbranched semiconductor nanocrystal particle.

In a fourth embodiment, the present invention provides a photovoltaic device comprising a cathode; an anode; and a photoactive layer comprising a monolayer of the hyperbranched semiconductor nanocrystal particle of the present invention, wherein the photoactive layer is disposed between the cathode and the anode.

### BRIEF DESCRIPTION OF THE DRAWINGS

FIGS. 1a-1e show transmission electron microscope images of hyperbranched particles grown under reaction conditions A-E. The scale bars represent 100 nm (for the three columns of close-up images on the left) and 500 nm (for the overview images in the column on the right).

FIGS. 1f-1h show the average diameters, the projected solidity, and the number of tips on the particle perimeter as counted on the two-dimensional TEM projection for the batches A-E as shown in FIGS. 1a-1e.

FIGS. 2a-2c show the effects of increasing amounts of monofunctional phosphonic acid on particle morphology. All scale bars represent 100 nm. The branched nanocrystal in FIG. 2c has a hexapod structure.

FIGS. 2d-2f show the effects of increasing amounts of bifunctional carboxyethyl phosphonic acid (CEPA) on particle morphology. All scale bars represent 100 nm.

FIGS. 2g-2i show the effects of increasing amounts of ethyl diphosphonic acid (EDPA) on particle morphology. All scale bars represent 100 nm.

FIGS. 3a and 3b show the evolution of branching over time as observed by transmission electron microscope (TEM) for crystal growth in (3a) CdTe particles and (3b) CdSe particles.

FIG. 4a shows a simple schematic drawing showing the cross-sectional morphology of a traditional hybrid nanocrystal-polymer solar cell based on nanorods.

FIG. 4b shows a simple schematic drawing showing the cross-sectional morphology of a hybrid nanocrystal-polymer solar cell based on complex hyperbranched nanocrystals, according to an embodiment of the invention.

FIG. 4c shows a transmission electron micrograph that shows the 3-D structure of CdSe hyperbranched nanocrystals. The scale bar represents 100 nm.

FIG. 4d shows a transmission electron micrograph that shows the 3-D structure of CdTe hyperbranched nanocrystals. The scale bar represents 100 nm.

FIG. 5a shows a series of transmission electron micrographs that show the morphologies of hybrid blends employing hyperbranched nanocrystals. Loading percentages (in upper left corner of each image) represent the concentration of CdSe by volume in the spin-casting solution. The scale bar represents 500 nm.

FIG. 5b shows a series of transmission electron micrographs that show the morphologies of hybrid blends employing nanorods. Loading percentages (in upper left corner of each image) represent the concentration of CdSe by volume in the spin-casting solution. The scale bar represents 500 nm.

FIG. 6a shows open circuit voltage as a function of CdSe concentration (as shown in FIGS. 5a and 5b) for hyperbranched nanocrystal (solid circles) and nanorod (open circle) solar cells. Data points represent the highest measured values from a set of 8 regions of each substrate.

FIG. 6b shows short circuit current as a function of CdSe concentration (as shown in FIGS. 5a and 5b) for hyperbranched nanocrystal (solid circles) and nanorod (open circle) solar cells. Data points represent the highest measured values from a set of 8 regions of each substrate.

FIG. 6c shows fill factor as a function of CdSe concentration (as shown in FIGS. 5a and 5b) for hyperbranched nanocrystal (solid circles) and nanorod (open circle) solar cells. Data points represent the highest measured values from a set of 8 regions of each substrate.

FIG. 6d shows power conversion efficiency as a function of CdSe concentration (as shown in FIGS. 5a and 5b) for hyperbranched nanocrystal (solid circles) and nanorod (open circle) solar cells. Data points represent the highest measured values from a set of 8 regions of each substrate.

FIG. 7a shows photocurrent spectra (plots of extended quantum efficiency as a function of wavelength) of hybrid cells based on hyperbranched-particles at CdSe concentrations shown in FIG. 5a.

FIG. 7b shows photocurrent spectra (plots of extended quantum efficiency as a function of wavelength) of hybrid cells based on nanorods at CdSe concentrations shown in FIG. 5b.

FIG. 7c shows a plot of S as a function of CdSe concentration for nanorod (open circle) and hyperbranched nanocrystal (solid circle) solar cells.

FIG. 8a shows current-voltage characteristics for a hyperbranched nanocrystal cell with a one-sun AM1.5G efficiency of 2.18%.

FIG. 8b shows a transmission electron micrograph that illustrates the detailed morphology of the hyperbranched nanocrystal cell measured in FIG. 8a. The scale bar represents 20 nm.

FIGS. 9a-9e show a three-dimensional structure of the hyper-branched particles as obtained by TEM tomography (9a-9d) and SEM (9e). For TEM tomography, images of the same particle are recorded at different tilt angles in 2-degree steps, e.g. 70 degree (9a), 0 degree (9b) and −62 degree (9c) (scale bar is 100 nm). The small dots are 5 nm gold particles used as alignment marks in order to create a well aligned stack of images, which is then transformed into a full, three-dimensional reconstruction. A side view of this reconstruction is shown in 9d, with a multiple branching point at the arm pointing upwards from the surface shown in detail in the inset.

FIGS. 10a-10d show the effect of impurities in the solvent (TOPO) on particle shape. All experiments were done under the same reaction conditions according to the basic protocol. Different TOPO batch was used in each case. For the experiment (a) the TOPO was purchased from Sigma-Aldrich with 99% purity. For experiment (b) the TOPO was purchased from Alfa Aesar with 96% purity. For experiment (c) the TOPO was purchased from ACROS with 99% purity. For experiment (d) a different batch of TOPO was purchased from Sigma-Aldrich with 99% purity (different batch number than a).

FIGS. 11a-11c show the effect of TDPA/CEPA ratio on particle shape. The TDPA/CEPA ratio was varied from 37:1 (11a), over 11:1 (11b) to 6.5:1 (11c). A ratio of 37:1 leads to rods, bipods, tetrapods with long arms but no further branching (11a). A ratio of 11:1 produces hyper-branched particles (11b). A ratio of 6.5:1 resulted in aggregations of spherical particles with no specific shape (11c). Scale bars are 100 nm.

FIG. 12 shows the X-ray diffraction spectra for CdSe (12a) and CdTe (12b) hyperbranched nanocrystals. The peak positions match those expected for the wurtzite phase for both materials. The 002 peaks are sharper than neighboring peaks which is consistent with crystalline domains elongated along the 002 direction. The incident radiation used was Co Kα with wavelength of 1.789 Å.

FIGS. 13 and 14 show schematic illustrations of hyperbranched particles according to embodiments of the invention.

### DETAILED DESCRIPTION OF THE INVENTION

### I. General

Embodiments of the present invention are drawn to a new type of (CdSe or CdTe) nanocrystal particle, the hyperbranched nanocrystal particle. These hyperbranched nanocrystal particles have many branching points at random locations, including the core and along each of the growing arms of the nanocrystal particle. In some instances, preparation of the hyperbranched semiconductor nanocrystal particles proceeds through a tetrapod followed by formation of additional arms from either the core of the tetrapod, the intermediate portion of other arms, or from the terminus of other arms. The hyperbranched nanocrystal particles differ from tetrapods in that the hyperbranched nanocrystal particles can have more than 4 arms extending from the central core, and can have branch points along the sides of the arms. The increased branching of the hyperbranched nanocrystal particles can be realized using a heterobifunctional surfactant, such as 2-carboxy ethyl phosphonic acid (CEPA).

The three-dimensional volume of the hyperbranched semiconductor nanocrystal particles allows each particle to be in contact with both an anode and a cathode in a photovoltaic device. Each hyperbranched semiconductor nanocrystal particle can form part of a discrete photovoltaic device, while a monolayer of hyperbranched semiconductor nanocrystal particles can form an array of nanoscale photovoltaic devices.

### II. Definitions

As used herein, the term “alkyl” refers to a straight or branched, saturated, aliphatic radical having the number of carbon atoms indicated. For example, C₁-C₆ alkyl includes, but is not limited to, methyl, ethyl, propyl, butyl, pentyl, hexyl, iso-propyl, iso-butyl, sec-butyl, tert-butyl, etc.

As used herein, the term “amine” refers to a straight or branched, saturated, radical having an alkyl chain of 1-10 carbon atoms and one or more amino groups. The alkyl portion of the amine can be methyl, ethyl, propyl, butyl, pentyl, hexyl, iso-propyl, iso-butyl, sec-butyl, tert-butyl, etc. The amino groups can be primary, secondary or tertiary. The alkyl amine can be further substituted with a hydroxy group. Amines useful in the present invention include, but are not limited to, ethyl amine, propyl amine, isopropyl amine, ethylene diamine and ethanolamine. One of skill in the art will appreciate that other amines are useful in the present invention.

As used herein, the term “aryl” refers to a monocyclic or fused bicyclic, tricyclic or greater, aromatic ring assembly containing 6 to 16 ring carbon atoms. For example, aryl may be phenyl, benzyl or naphthyl, preferably phenyl. “Arylene” means a divalent radical derived from an aryl group. Aryl groups can be mono-, di- or tri-substituted by one, two or three radicals selected from alkyl, alkoxy, aryl, hydroxy, halogen, cyano, amino, amino-alkyl, trifluoromethyl, alkylenedioxy and oxy-C₂-C₃-alkylene; all of which are optionally further substituted, for instance as hereinbefore defined; or 1- or 2-naphthyl; or 1- or 2-phenanthrenyl. Alkylenedioxy is a divalent substitute attached to two adjacent carbon atoms of phenyl, e.g. methylenedioxy or ethylenedioxy. Oxy-C₂-C₃-alkylene is also a divalent substituent attached to two adjacent carbon atoms of phenyl, e.g. oxyethylene or oxypropylene. An example for oxy-C₂-C₃-alkylene-phenyl is 2,3-dihydrobenzofuran-5-yl.

As used herein, the term “contacting” refers to the process of bringing into contact at least two distinct species such that they can react. It should be appreciated, however, the resulting reaction product can be produced directly from a reaction between the added reagents or from an intermediate from one or more of the added reagents which can be produced in the reaction mixture.

As used herein, the term “extending” refers to an arm of the hyperbranched semiconductor nanocrystal particle growing outwards and away from the side of another arm or from the core of the hyperbranched semiconductor nanocrystal particle.

As used herein, the term “fatty acid” refers to a carboxylic acid having an aliphatic tail, typically from 4 to 30 carbon atoms long. Fatty acids can be saturated, mono-unsaturated or poly-unsaturated. Fatty acids useful in the present invention also include branched fatty acids such as iso-fatty acids. Examples of fatty acids useful in the present invention, include, but are not limited to, butyric acid (C4), caproic acid (C6), caprylic acid (C8), capric acid (C10), lauric acid (C12), myristic acid (C14), palmitic acid (C16), palmitoleic acid (C16), stearic acid (C18), isostearic acid (C18), oleic acid (C18), vaccenic acid (C18), linoleic acid (C18), alpha-linoleic acid (C18), gamma-linolenic acid (C18), arachidic acid (C20), gadoleic acid (C20), arachidonic acid (C20), eicosapentaenoic acid (C20), behenic acid (C22), erucic acid (C22), docosahexaenoic acid (C22), lignoceric acid (C24) and hexacosanoic acid (C26). One of skill in the art will appreciate that other fatty acids are useful in the present invention.

As used herein, the term “hyperbranched semiconductor nanocrystal particle” refers to a semiconductor nanocrystal particle having a dendritic structure with branch points that can be randomly placed or regularly placed, or semiconductor nanocrystal particles having at least 5 arms extending from a single point. In The hyperbranched semiconductor nanocrystal particle comprises a plurality of arms (such as first and second, primary and secondary arms), wherein each arm has an intermediate portion and opposing terminal portions. In addition, the hyperbranched semiconductor nanocrystal particle comprises a core formed from the terminal portion of at least one arm.

As used herein, the term “material exhibiting polytypism” refers to materials that are found in more than one crystal structure under similar conditions (temperature, pressure, etc.) Examples of materials exhibiting polytypism include, but are not limited to, silicon carbide (SiC) and zinc sulfide (ZnS). One of skill in the art will appreciate that other materials exhibiting polytypism are useful in the present invention.

As used herein, the term “metal” refers to elements of the periodic table such as alkali metals, alkali earth metals, transition metals and post-transition metals. Alkali metals include Li, Na, K, Rb and Cs. Alkaline earth metals include Be, Mg, Ca, Sr and Ba. Transition metals include Sc, Ti, V, Cr, Mn, Fe, Co, Ni, Cu, Zn, Y, Zr, Nb, Mo, Tc, Ru, Rh, Pd, Ag, Cd, La, Hf, Ta, W, Re, Os, Ir, Pt, Au, Hg and Ac. Post-transition metals include Al, Ga, In, Tl, Ge, Sn, Pb, Sb, Bi, and Po. One of skill in the art will appreciate that the metals described above can each adopt several different oxidation states, all of which are useful in the present invention. In some instances, the most stable oxidation state is formed, but other oxidation states are useful in the present invention.

As used herein, the term “monolayer” refers to a single, closely packed layer of atoms, molecules, or cells on a surface.

As used herein, the term “phosphine” refers to compounds or functional groups of the formula: R₃P, where R is any functional group, such as H, alkyl or aryl. Each R group can be the same or different. When R is an alkyl group, the alkyl group can have from 1 to 30 carbon atoms. Aryl groups include, but are not limited to, phenyl and naphthyl. Phosphines useful in the present invention include, but are not limited to, tri-n-octylphosphine. One of skill in the art will appreciate that other phosphines are useful in the present invention.

As used herein, the term “phosphine oxide” refers to compounds or functional groups of the formula: R₃P(O), where each R is any functional group, such as H, alkyl or aryl. When R is an alkyl group, the alkyl group can have from 1 to 30 carbon atoms. Phosphine oxides useful in the present invention include, but are not limited to, tri-n-octylphosphine oxide. One of skill in the art will appreciate that other phosphine oxides are useful in the present invention.

As used herein, the term “phosphonic acid” refers to compounds or functional groups of the formula: R(OR)₂P(O), where each R is any functional group, such as H, alkyl or aryl. When R is an alkyl group, the alkyl group can have from 1 to 30 carbon atoms. Phosphonic acids useful in the present invention include, but are not limited to, n-tetradecylphosphonic acid, 1,2-ethylene diphosphonic acid and 2-carboxyethylphosphonic acid. One of skill in the art will appreciate that other phosphonic acids are useful in the present invention.

As used herein, the term “phosphinic acid” refers to compounds or functional groups of the formula: RR(OR)P(O), where each R is any functional group, such as H, alkyl or aryl. When R is an alkyl group, the alkyl group can have from 1 to 30 carbon atoms. One of skill in the art will appreciate that other phosphinic acids are useful in the present invention.

As used herein, the term “photoactive layer” refers to a layer comprising a monolayer of the hyperbranched semiconductor nanocrystal particles, such that the photoactive layer converts light into electricity.

As used herein, the term “semiconductor” refers to a solid material with an electrical conductivity in between that of a conductor and that of an insulator. Semiconductors may be elemental materials such as silicon and germanium, or compound semiconductors such as cadmium telluride, cadmium selenide, gallium arsenide and indium phosphide, or alloys such as silicon germanium or aluminum gallium arsenide. See discussion below for additional semiconductors useful in the present invention.

As used herein, the term “surfactant mixture” refers to a mixture comprising at least one surfactant. Surfactants useful in the surfactant mixture of the present invention are those having functional groups that include, but are not limited to, a carboxylic acid group, an amine group, a phosphonic acid group, a phosphine group and a phosphine oxide group. The surfactants of the present invention can be monofunctional, having one surfactant functional group, or bifunctional, having two surfactant functional groups. The surfactant functional groups of a bifunctional surfactant can be the same or different. Monofunctional surfactants include, but are not limited to, a phosphine, a phosphonic acid, a phosphine oxide, an amine and a fatty acid, such as tri-n-octylphosphine oxide (TOPO), n-tetradecylphosphonic acid (TDPA), n-hexylphosphonic acid (HPA) and trioctylphosphine (TOP). Bifunctional surfactants include, but are not limited to, 1,2-ethylene diphosphonic acid (EDPA) 2-carboxyethylphosphonic acid (CEPA). One of skill in the art will appreciate that other surfactants are useful in the present invention.

### III. Hyperbranched Semiconductor Nanocrystal Particles

Hyperbranched semiconductor nanocrystal particles may comprise any number of branch points and can be prepared from any suitable material. The hyperbranched semiconductor nanocrystal particles may have a dendritic structure with randomly placed branch points rather than regularly placed branch points. The hyperbranched semiconductor nanocrystal particles comprise a plurality of arms and a core, wherein each arm has an intermediate portion and two opposing terminal portions, such that arms can extend and grow either from the core, the intermediate portion of another arm or the terminus of another arm. The core consists of a central point from which several arms extend. The core of a hyperbranched semiconductor nanocrystal particle is formed from the joining of a terminal portion from each of several arms.

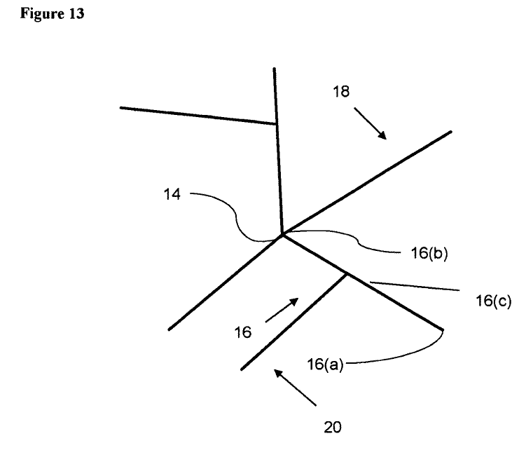

In some embodiments, referring to FIG. 13, the present invention provides a hyperbranched semiconductor nanocrystal particle comprising a first arm 16, wherein the first arm 16 comprises an intermediate portion 16(c) and two opposing terminal portions 16(a), 16(b); and a second arm 20, extending from the intermediate portion 16(c) of the first arm 16. One of the opposing terminal portions 16(a) and 16(b) can also form a core. In FIG. 13, opposing terminal portion 16(b) forms the core, 14. In addition, where the second arm 20 joins intermediate portion of 16(c) of the first arm 16, is termed a branch point. The hyperbranched semiconductor nanocrystal particle can further comprise a plurality of arms, such as 18, that can grow from the core 14 or from the intermediate portion of another arm.

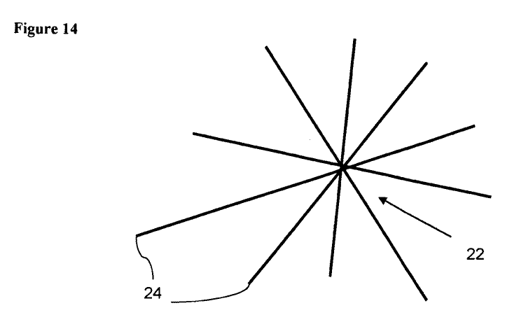

In other embodiments, referring to FIG. 14, the present invention provides a hyperbranched semiconductor nanocrystal particle comprising at least five primary arms 24 extending from a core 22, wherein each primary arm 24 comprises an intermediate portion and opposing terminal portions, wherein the core comprises one terminal portion of each of the primary arms 24.

In some embodiments, the present invention provides a hyperbranched semiconductor nanocrystal particle comprising a first arm, wherein the first arm comprises an intermediate portion and opposing terminal portions; and a second arm, extending from the intermediate portion of the first arm. In another embodiment, the hyperbranched semiconductor nanocrystal particle further comprises secondary arms, wherein each secondary arm comprises an intermediate portion and opposing terminal portions, wherein each secondary arm extends from the intermediate portion of one of the primary arms or from the intermediate portion of another of the secondary arms.

In other embodiments, the present invention provides a hyperbranched semiconductor nanocrystal particle comprising at least five primary arms extending from a core, wherein each primary arm comprises an intermediate portion and opposing terminal portions, wherein the core comprises the junction of a terminal portion of each of the primary arms.

In some other embodiments, the present invention provides a hyperbranched semiconductor nanocrystal particle wherein one of the terminal portions of the first arm is a core. In some other embodiments, the hyperbranched semiconductor nanocrystal particle further comprises a plurality of arms each comprising an intermediate portion and opposing terminal portions, wherein each arm extends from either the intermediate portion of another arm or the core of the first arm. In still other embodiments, the hyperbranched semiconductor nanocrystal particle further comprises at least 10 arms. In yet other embodiments, the hyperbranched semiconductor nanocrystal further comprises at least 6 branch points.

Semiconductors useful in the hyperbranched nanocrystal particles of the present invention include any material whose electrical conductivity is in between that of a conductor and that of an insulator. Semiconductors useful in the present invention include, but are not limited to a Group I-VII semiconductor, a Group II-VI semiconductor, a Group II-V semiconductor, a Group III-V semiconductor, a Group IV semiconductor, a Group IV-VI semiconductor, a Group V-VI semiconductor, a metal or a material exhibiting polytypism.

In some embodiments, Group I-VII semiconductors useful in the present invention include any semiconductor comprising both a Group I element (Cu, Ag, Au) and a Group VII element (F, Cl, Br, I, At). Group I-VII semiconductors include, but are not limited to, Cuprous chloride (CuCl). One of skill in the art will appreciate that other Group I-VII semiconductors are useful in the present invention.

In other embodiments, Group II-V semiconductors useful in the present invention include any semiconductor comprising both a Group II element (Zn, Cd, Hg) and a Group V element (N, P, As, Sb, Bi). Group II-V semiconductors include, but are not limited to, Cadmium phosphide (Cd₃P₂), Cadmium arsenide (Cd₃As₂), Cadmium antimonide (Cd₃Sb₂), Zinc phosphide (Zn₃P₂), Zinc arsenide (Zn₃As₂) and Zinc antimonide (Zn₃Sb₂). One of skill in the art will appreciate that other Group II-V semiconductors are useful in the present invention.

In another embodiment, Group II-VI semiconductors useful in the present invention include any semiconductor comprising both a Group II element (Zn, Cd, Hg) and a Group VI element (O, S, Se, Te, Po). Group II-VI semiconductors include, but are not limited to, Cadmium selenide (CdSe), Cadmium sulfide (CdS), Cadmium telluride (CdTe), Zinc oxide (ZnO), Zinc selenide (ZnSe), Zinc sulfide (ZnS), Zinc telluride (ZnTe), Cadmium zinc telluride (CdZnTe, CZT), Mercury cadmium telluride (HgCdTe), Mercury zinc telluride (HgZnTe) and Mercury zinc selenide (HgZnSe). One of skill in the art will appreciate that other Group II-VI semiconductors are useful in the present invention.

In some embodiments, the hyperbranched semiconductor nanocrystal particle comprises a Group II-VI semiconductor. In other embodiments, the Group II-VI semiconductor is selected from the group consisting of CdSe, CdTe, CdS, ZnO, ZnSe, ZnS, ZnTe, CdZnTe, HgCdTe, HgZnTe and HgZnSe. In still other embodiments, the Group II-VI semiconductor is selected from the group consisting of CdSe and CdTe. In another embodiment, the hyperbranched semiconductor nanocrystal particle comprises CdSe. In still another embodiment, the hyperbranched semiconductor nanocrystal particle comprises CdTe.

In other embodiments, Group III-V semiconductors useful in the present invention include any semiconductor comprising both a Group III element (B, Al, Ga, In, T1) and a Group V element (N, P, As, Sb, Bi). Group III-V semiconductors include, but are not limited to, Aluminum antimonide (AlSb), Aluminum arsenide (AlAs), Aluminum nitride (AlN), Aluminum phosphide (AlP), Boron nitride (BN), Boron phosphide (BP), Boron arsenide (BAs), Gallium antimonide (GaSb), Gallium arsenide (GaAs), Gallium nitride (GaN), Gallium phosphide (GaP), Indium antimonide (InSb), Indium arsenide (InAs), Indium nitride (InN), Indium phosphide (InP), Aluminum gallium arsenide (AlGaAs, AlₓGa₁₋ₓAs), Indium gallium arsenide (InGaAs, InₓGa₁₋ₓAs), Aluminum indium arsenide (AlInAs), Aluminum indium antimonide (AlInSb), Gallium arsenide nitride (GaAsN), Gallium arsenide phosphide (GaAsP), Aluminum gallium nitride (AlGaN), Aluminum gallium phosphide (AlGaP), Indium gallium nitride (InGaN), Indium arsenide antimonide (InAsSb), Indium gallium antimonide (InGaSb), Aluminum gallium indium phosphide (AlGaInP, also InAlGaP, InGaAlP, AlInGaP), Aluminum gallium arsenide phosphide (AlGaAsP), Indium gallium arsenide phosphide (InGaAsP), Aluminum indium arsenide phosphide (AlInAsP), Aluminum gallium arsenide nitride (AlGaAsN), Indium gallium arsenide nitride (InGaAsN), Indium aluminum arsenide nitride (InAlAsN) and Gallium indium nitride arsenide antimonide (GaInNAsSb). One of skill in the art will appreciate that other Group III-V semiconductors are useful in the present invention.

In some embodiments, Group IV semiconductors useful in the present invention are those semiconductors comprising only Group IV elements (C, Si and Ge) and can be elemental or compound semiconductors. Group IV semiconductors include, but are not limited to, diamond (C), silicon (Si), germanium (Ge), silicon carbide (SiC) and silicon germanide (SiGe). One of skill in the art will appreciate that other Group IV semiconductors are useful in the present invention.

In other embodiments, Group IV-VI semiconductors useful in the present invention include any semiconductor comprising both a Group IV element (C, Si, Ge, Sn, Pb) and a Group VI element (O, S, Se, Te, Po), as well as other elements. Group IV-VI semiconductors include, but are not limited to, Lead selenide (PbSe), Lead sulfide (PbS), Lead telluride (PbTe), Tin sulfide (SnS), Tin telluride (SnTe), lead tin telluride (PbSnTe), Thallium tin telluride (Tl₂SnTe₅) and Thallium germanium telluride (Tl₂GeTe₅). One of skill in the art will appreciate that other Group IV-VI semiconductors are useful in the present In some embodiments, Group V-VI semiconductors useful in the present invention include any semiconductor comprising both a Group V element (N, P, As, Sb, Bi) and a Group VI element (O, S, Se, Te, Po). Group V-VI semiconductors include, but are not limited to, Bismuth telluride (Bi₂Te₃). One of skill in the art will appreciate that other Group V-VI semiconductors are useful in the present invention.

Additional semiconductors useful in the present invention include, but are not limited to, layered semiconductors. Layered semiconductors include, but are not limited to, Lead(II) iodide (PbI₂), Molybdenum disulfide (MoS₂), Gallium Selenide (GaSe), Tin sulfide (SnS) and Bismuth Sulfide (Bi₂S₃). Other semiconductors useful in the present invention include, but are not limited to, Copper indium gallium selenide (CIGS), Platinum silicide (PtSi), Bismuth(III) iodide (BiI₃), Mercury(II) iodide (HgI₂), Thallium(I) bromide (TlBr), Titanium dioxide: anatase (TiO₂), Copper(I) oxide (Cu₂O), Copper(II) oxide (CuO), Uranium dioxide (UO₂) and Uranium trioxide (UO₃). One of skill in the art will appreciate that other semiconductors are useful in the present invention.

In some embodiments, the particles can comprise a metal. Metals useful in the present invention include, but are not limited to, the alkali metals, alkali earth metals, transition metals and post-transition metals. Alkali metals include Li, Na, K, Rb and Cs. Alkaline earth metals include Be, Mg, Ca, Sr and Ba. Transition metals include Sc, Ti, V, Cr, Mn, Fe, Co, Ni, Cu, Zn, Y, Zr, Nb, Mo, Tc, Ru, Rh, Pd, Ag, Cd, La, Hf, Ta, W, Re, Os, Ir, Pt, Au, Hg and Ac. Post-transition metals include Al, Ga, In, Tl, Ge, Sn, Pb, Sb, Bi, and Po. One of skill in the art will appreciate that the metals described above can each adopt several different oxidation states, all of which are useful in the present invention. In some instances, the most stable oxidation state is formed, but other oxidation states are useful in the present invention.

In other embodiments, the particles may comprise a dielectric material such as SiC, SiN or any other material that can exhibit polytypism. Some metals such as Fe, Ni, Cu, Ag, Au, Pd, Pt, Co and others may also exhibit polytypism and can be used in embodiments of the invention.

In some embodiments, the present invention provides a hyperbranched semiconductor nanocrystal particle formed by contacting a first semiconductor precursor, a second semiconductor precursor and a surfactant mixture comprising a bifunctional surfactant, thereby preparing a hyperbranched semiconductor nanocrystal particle.

### IV. Method of Preparing Hyperbranched Semiconductor Nanoparticles

In another embodiment of the invention, a process for preparing hyperbranched semiconductor nanocrystals and inorganic dendrimers of precisely controlled generation involves varying the amount and kind of organic surfactant used in the process. The lengths of the arms and the degree of branching for “hyperbranched” semiconductor nanocrystals can be controlled independently. The shapes range from “thorny balls”, to treelike ramified structures, to delicate “spider-net” particles. The various intricate shapes arise from a delicate balance of branching and extension.

In some embodiments, hyperbranched nanocrystals are grown for the II-VI class of semiconductors, such as CdSe and CdTe, which have an intermediate fractional ionicity of bonds, poising them between two possible crystal structures. The basic branch point consists of a pyramidally shaped cubic zinc blende unit with hexagonal wurtzite arms projecting outward at the tetrahedral angle. The two crystal structures are close in energy and can occur at the same temperature and pressure (polytypism). Switching between the two structures can be driven kinetically; fast growth rates favors the cubic phase, while slow growth rates favor the hexagonal phase. Preferential capping or stabilization by a surfactant of some crystal faces can change the kinetics and relative stability of crystal faces, a phenomenon also seen in the growth of snowflakes. Organic stabilizers such as phosphonic acids can be used to alter the crossover threshold, with higher phosphonic acid concentrations favoring branching at relatively lower concentrations of monomer and hence lower growth rate.

In some embodiments, the present invention provides a method of preparing a hyperbranched semiconductor nanocrystal particle of the present invention, comprising contacting a first semiconductor precursor, a second semiconductor precursor and a surfactant mixture comprising a bifunctional surfactant, thereby preparing a hyperbranched semiconductor nanocrystal particle.

A. Semiconductor Precursors

The types of precursors used to form the hyperbranched, nanocrystal particles depend on the particular hyperbranched nanocrystal particles to be formed. In some embodiments, the precursors used to synthesize the hyperbranched nanocrystal particles include Group II, III, IV, V, and/or VI semiconductor precursors. For example, in embodiments of the invention, hyperbranched semiconductor nanocrystal particles including a Group II-VI compound semiconductor can be the reaction product of at least one precursor containing a Group II metal containing precursor and at least one precursor containing a Group VI element, or a precursor containing both a Group II and a Group VI element. In other embodiments of the invention, hyperbranched semiconductor nanocrystal particles including a Group III-V compound semiconductor can be the reaction product of at least one precursor containing a Group III element and at least one precursor containing a Group V element, or a precursor containing both a Group III and a Group V element. Other exemplary precursors, surfactants, and solvents can be found in U.S. Pat. Nos. 6,225,198 and 6,306,736. These U.S. patents are herein incorporated by reference in their entirety for all purposes.

If Group III-V hyperbranched semiconductor nanocrystal particles are to be synthesized, a Group III precursor, such as elemental Ga, In, Al, or any compound containing a Group III precursor, such as a Ga(III) salt, In(III)salt, or Al(III) salt (e.g., of a halide, or corresponding metal-carbon trialkyls) can be reacted directly with an arsenic, phosphorus, or antimony source such as arsine, phosphine, or stibine; an alkyl arsine, phosphine or stibine; or an alkyl silyl arsine, phosphine or stibine in liquid phase at an elevated temperature. Representative metal sources include GaCl₃, GaBr₃, GaI₃, InCl₃, InBr₃, AlCl₃, Ga(Me)₃, Ga(Et)₃, Ga(Bu)₃, or the like. Representative arsenic, phosphorus and selenium sources include AsH₃, PH₃, SeH₃, AsH₂ (carbon alkyl), As(carbon alkyl)₃, P(carbon alkyl)₃, As(Si(carbon alkyl)₃)₃, P(Si(carbon alkyl)₃)₃, Se(Si(carbon alkyl)₃)₃ and the like. Although specific examples of precursors are provided, any Group III or V element and any compound containing such an element can be used in embodiments of the invention.

If Group II-VI hyperbranched semiconductor nanocrystal particles are to be synthesized, they may be the product of a reaction containing at least one precursor comprising a Group II element such as Zn, Cd, or Hg, or any Group II containing molecule such as a metal, salt, oxide, organometallic compound, and at least one precursor comprising a Group VI element such as O, S, Se, or Te, or any Group VI containing molecule such as a metal, salt, oxide, organometallic compound, or a precursor containing both a Group II element (Zn, Cd, or Hg) and a Group VI element (S, Se, or Te). Those of skill in the art can select the appropriate precursors to form the appropriate compound semiconductor. For example, Cd(CH₃) and Se:TOP are examples of precursors respectively containing Group II and Group VI elements that can be used to form CdSe hyperbranched nanocrystal particles.

The precursors may be dissolved in any liquid compatible with the surfactant mixture. Examples of organic liquids include polar organic solvents including trialkyl phosphine, e.g., tributyl phosphine. In some embodiments, the precursors may be dissolved in the same solvent or may be dissolved separately to form two or more precursor solutions.

B. Surfactant Mixture

Embodiments of the invention can use a surfactant mixture to make the hyperbranched semiconductor nanocrystal particles. The surfactant mixture can be a high boiling point liquid mixture of two or more reactive or non-reactive organic surfactants. The mixture of these organic surfactants is capable of promoting the growth of branched semiconductor nanocrystal particles. The surfactant mixture can comprise both monofunctional and bifunctional surfactants.

The surfactant mixture can have a boiling point that is high enough so that a reaction between, for example, the Group II and Group VI precursors, or the Group III and Group V precursors, can take place to form the desired hyperbranched semiconductor nanocrystal particles. For example, in some embodiments, the surfactant mixture can have a boiling point between about 200° C. to about 400° C. One of skill in the art will appreciate that other temperatures are useful in the present invention.

The surfactant mixture may include any suitable number of different surfactants. For example, the surfactant mixture may include a first organic surfactant and a second organic surfactant. Third, fourth, fifth, etc. surfactants can also be used. For example, in some embodiments of the invention, at least one or two of the surfactants can be selected from the group consisting of a phosphine, a phosphonic acid, a phosphine oxide, an amine and a fatty acid. As noted above, the surfactant mixture can be capable of being heated to a crystal-growing temperature, and can promote the growth of branched semiconductor nanocrystal particles such as tetrapods.

In some embodiments, one surfactant in the surfactant mixture comprises a phosphorus-containing surfactant capable of withstanding such crystal-growing temperatures. Examples of such phosphorus-containing liquid surfactants include liquid surfactants such as 3-30 (or larger) carbon trialkyl phosphines (e.g., tributyl phosphine), or 3-30 or larger carbon trialkyl phosphine oxides (e.g., trioctyl phosphine oxide or “TOPO”). Other surfactants can include functional groups such as amines, carboxylic acids and any other groups as long as they are stable.

In another embodiment, the surfactant mixture further comprises other surfactants capable of being heated to crystal-growing temperatures and capable of promoting the growth of hyperbranched semiconductor nanocrystal particles. Preferably, the liquid surfactant capable of promoting the growth of hyperbranched semiconductor nanocrystal particles comprises a phosphorus-containing surfactant capable of withstanding such crystal-growing temperatures. Surfactants of this type can comprise an organic-substituted acid, or acid salt surfactant containing phosphorus such as, for example, phosphonic and phosphinic acids. Suitable phosphinic acids can include mono and diphosphinic acids having the general formula R′RₓH₍₁₋ₓ₎P(O)OH, where R and R′ are the same or different 3-30 carbon (but preferably 3-30 carbon) organic groups such as alkyl or aryl groups, and x is 0-1. In some embodiments, surfactants of this type comprise a 3-30 carbon alkyl phosphonic acid, e.g., octadecyl phosphonic acid.

Surfactants capable of being heated to crystal-growing temperatures and promoting the growth of hyperbranched semiconductor nanocrystal particles are preferably a long chain length phosphonic acid. Short chain length phosphonic acids are defined as those having an alkyl chain length of less than or equal to about 10 carbon atoms. Long chain length phosphonic acids are defined as those having an alkyl chain length of greater than or equal to about 10 carbon atoms. In preferred embodiments, the phosphonic acid is at least 14 carbon atoms long. Examples of phosphonic acid surfactants include, but are not limited to, octyldecylphosphonic acid (ODPA) and n-tetradecylphosphonic acid (TDPA). These long chain length phosphonic acids can help to promote the growth of hexagonal crystals. One of skill in the art will appreciate that phosphonic acids help to promote the growth of the hyperbranched semiconductor nanocrystal particles of the present invention.

When the surfactant mixture includes a fatty acid, the fatty acid refers to a carboxylic acid having an aliphatic tail, typically from 4 to 30 carbon atoms long. Fatty acids can be saturated, mono-unsaturated or poly-unsaturated. Fatty acids useful in the present invention also include branched fatty acids such as iso-fatty acids. Examples of fatty acids useful in the present invention, include, but are not limited to, butyric acid (C4), caproic acid (C6), caprylic acid (C8), capric acid (C10), lauric acid (C12), myristic acid (C14), palmitic acid (C16), palmitoleic acid (C16), stearic acid (C18), isostearic acid (C18), oleic acid (C18), vaccenic acid (C18), linoleic acid (C18), alpha-linoleic acid (C18), gamma-linolenic acid (C18), arachidic acid (C20), gadoleic acid (C20), arachidonic acid (C20), eicosapentaenoic acid (C20), behenic acid (C22), erucic acid (C22), docosahexaenoic acid (C22), lignoceric acid (C24) and hexacosanoic acid (C26). One of skill in the art will appreciate that other fatty acids are useful in the present invention.

In some embodiments, the present invention provides a method of preparing a hyperbranched semiconductor nanocrystal particle of the present invention, comprising contacting a first semiconductor precursor, a second semiconductor precursor and a surfactant mixture comprising a bifunctional surfactant, thereby preparing a hyperbranched semiconductor nanocrystal particle.

In some other embodiments, the first and second semiconductor precursors are in a surfactant mixture comprising at least one monofunctional surfactant and at least one bifunctional surfactant.

In another embodiment, the surfactant mixture comprises a monofunctional surfactant is selected from the group consisting of a phosphine, a phosphonic acid, a phosphinic acid, a phosphine oxide, an amine and a fatty acid. In other embodiments, the monofunctional surfactant is a member selected from the group consisting of propylphosphonic acid, n-tetradecylphosphonic acid (TDPA), tri-n-octyl phosphine oxide and tri-n-octylphosphine.

In other embodiments, the surfactant mixture contains a bifunctional surfactant having two functional groups each independently selected from the group consisting of a carboxylic acid group, an amine group, a phosphonic acid group, a phosphine group and a phosphine oxide group. Suitable bifunctional surfactants have an alkyl chain of from about 2 to about 30 carbon atoms in length. Bifunctional surfactants of the present invention include those having a carboxylic acid group and an amine group, a carboxylic acid group and a phosphonic acid group, a carboxylic acid group and a phosphonic acid group, a carboxylic acid group and a phosphine group, a carboxylic acid group and a phosphine oxide group, an amine group and a phosphonic acid group, an amine group and a phosphine group, an amine group and a phosphine oxide group, a phosphonic acid group and a phosphine group, a phosphonic acid group and a phosphine oxide group, and a phosphine group and a phosphine oxide group.

In a further embodiment, each bifunctional surfactant comprises two semiconductor binding groups each independently selected from the group consisting of a carboxylic acid group, an amine group, a phosphonic acid group, a phosphinic acid group, a phosphine group and a phosphine oxide group. In some embodiments, the bifunctional surfactant is 2-Carboxyethylphosphonic acid (CEPA) or 1,2-ethylene diphosphonic acid (EDPA). In another embodiment, the bifunctional surfactant is CEPA.

The monofunctional surfactants and the bifunctional surfactants can be present in the surfactant mixture in any useful ratio. In some embodiments, the ratio of monofunctional surfactant to bifunctional surfactant is 1:1, 2:1, 3:1, 4:1, 5:1, 6:1, 7:1, 8:1, 9:1, 10:1, 11:1, 12:1, 13:1, 14:1, 15:1, 16:1, 17:1, 18:1, 19:1, 20:1, 25:1, 30:1, 35:1, 40:1, 45:1 and 50:1. In some other embodiments, the ratio is from about 1:1 (mol/mol) to about 50:1 (mol/mol). In other embodiments, the ratio of monofunctional surfactant to bifunctional surfactant is from about 5:1 (mol/mol) to about 20:1 (mol/mol). In still other embodiments, the ratio of monofunctional surfactant to bifunctional surfactant is about 11:1 (mol/mol). In yet other embodiments, the monofunctional surfactant comprises n-tetradecylphosphonic acid (TDPA) and the bifunctional surfactant is 2-carboxyethylphosphonic acid (CEPA), and the ratio of TDPA:CEPA is about 11:1 (mol/mol).

The surfactant mixture of the present invention can comprise any combination of surfactants, including monofunctional and bifunctional surfactants. In some embodiments, the surfactant mixture comprises n-tetradecylphosphonic acid, tri-n-octyl phosphine oxide, tri-n-octylphosphine and 2-carboxyethylphosphonic acid. In other embodiments, the first semiconductor precursor is in a first surfactant mixture comprising n-tetradecylphosphonic acid, tri-n-octyl phosphine oxide, tri-n-octylphosphine and 2-carboxyethylphosphonic acid.

C. Process

Embodiments of the invention may include adding (e.g., injecting) precursors to a heated surfactant mixture, reducing a temperature of the mixture, thereby forming hyperbranched particles, and then separating the hyperbranched particles from the mixture.

In some embodiments of the present invention, a solution of one or more precursors can be slowly and/or quickly injected into a heated surfactant mixture. “Injecting precursors slowly” is a relative term that is readily determinable by one having ordinary skill in the art. It can include adding precursors drop by drop or no faster than 10 drops/sec, 5 drops/sec, 2 drops/sec, or 1 drop/sec. “Injecting precursors quickly” is also a relative term readily determinable by one having ordinary skill in the art. It can include adding precursors at a speed greater than 100 drops/sec, 20 drops/sec, or 10 drops/sec. For example, injecting precursors quickly can include emptying a 5 mL syringe holding the precursor as quickly as possible.

A solution of precursors can be injected into the surfactant mixture at a cold or low temperature solution so that immediately after the injection, the temperature of the hot mixture of surfactants drops to a second, lower temperature. Initially, the heated surfactant mixture can contain other precursors or no precursors. A pipette or a pressure nozzle can be used as an injection apparatus. The temperature can be kept constant during the nanocrystal growth. The resulting mixture is maintained at a first temperature, which results in the nucleation of seed crystals.

It is understood that the different precursors can be in their own separate solutions and these different solutions can be separately injected into the heated surfactant mixture in embodiments of the invention. For example, if CdSe hyperbranched nanocrystal particles are to be formed, a Cd precursor solution and a Se precursor solution can be separately and sequentially injected into a hot surfactant mixture to produce hyperbranched CdSe nanocrystal particles. The separate injection of precursors into a hot surfactant mixture is preferred as it results in better control of the reaction, which can allow a higher percentage of hyperbranched nanocrystal particles.

The precise reaction time may vary depending on the particular material used and the particular type of nanocrystal particles formed. In some embodiments, a 5 minute reaction time may be sufficient, while less than or more than 5 minutes may be desirable in other embodiments.

Subsequent nanocrystal growth can then stopped by a further reduction of the temperature to below the temperature at which nanocrystal growth occurs. Cessation of the crystal growth can be accomplished by rapidly reducing the temperature to ambient temperature or even lower, e.g., to less than 150, 100, 75, 50, or 25° C. or lower, e.g., by removing the heat source. The temperature can be reduced more rapidly if the solution is cooled with a stream of air, cold water, liquid nitrogen, dry ice or other cooling agent.

After they are formed, the hyperbranched semiconductor nanocrystal particles can be separated from the liquid medium that is used to form them. In some embodiments, a solvent such as methanol or acetone is added to the liquid medium containing the semiconductor nanocrystal particles to precipitate them. For example, CdSe particles are generally not soluble in polar solvents such as methanol or acetone. Any appropriate solvent can be added to precipitate the nanocrystal particles from the solution.

After the nanocrystal particles have precipitated, the precipitated nanocrystal particles are separated from the rest of the solution. In some embodiments, centrifuging can be used to separate the hyperbranched nanocrystal particles from other solution components. After centrifuging, the supernatant can be separated from the hyperbranched nanocrystal particles. The hyperbranched nanocrystal particles can then be stored as precipitate or can be dried in a vacuum.

Hyperbranched nanocrystals can be synthesized at elevated temperatures from a solution of metal ions in a mixture of tri-n-octylphosphine oxide (TOPO) and alkyl phosphonic acids resulting in a batch of particles with similar morphology. Just like snowflakes, no two particles look exactly alike as the complexity of their shapes increases, and yet particles of remarkably uniform character are obtained under a given set of conditions. Five different batches of nanocrystals were made under conditions A-E as shown in Table I.

TABLE I

| | Cd:PA | | | | |
|---|---|---|---|---|---|
| | (molar | | | | |
| Batch | ratio) | Cd | Te | Se | Figure Particle description |
| A | 1:3.2 | x mmol | 0.234 mmol | no | 1a tetrapods with long arms |
| | | | | | (~90 nm) |
| B | 1:3.2 | x mmol | 0.186 mmol | no | 1b tetrapods with longer |
| | | | | | arms (~300 nm) and |
| | | | | | additional branching, |
| C | 1:3.2 | x mmol | 0.117 mmol | no | 1c hyperbranched particles |
| | | | | | with diameters ~550 nm |
| D | 1:1.6 | yes | 0.117 mmol | no | 1d very thin particles |
| | | | | | with average arm |
| | | | | | thickness ~6 nm |
| E | | yes | no | yes | 1e starlike particles |

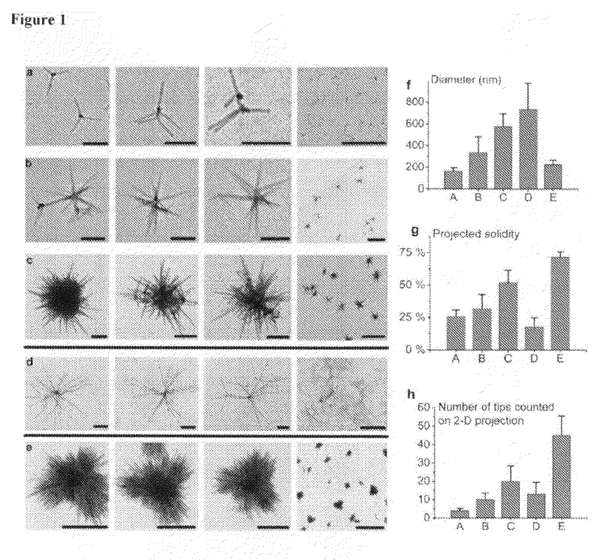

Representative examples of the variety of different shapes that resulted are shown in the transmission electron microscopy (TEM) images in FIGS. 1a-1e. The different morphologies in batches A-E are evident. Simple parameters such as particle diameter, “projected solidity”, and the number of tips pointing outward on the two-dimensional projection obtained from a statistical analysis of a large set of TEM images, can be used to compare particles quantitatively. The diagrams in FIGS. 1f-1h show the average diameters, the projected solidity, and the number of tips on the particle perimeter as counted on the two-dimensional TEM projection for the batches A-E as shown in FIGS. 1a-1e, respectively. The values are obtained from statistical analysis of approximately 50 images. The error bars indicate the standard deviation.

One of the parameters that controls the degree of branching is the concentration of the chalcogenide precursor. In the sequence of samples shown in FIGS. 1a-1c, the Cd precursor concentration is held fixed, and the total elapsed time is constant (20 min), while the Te precursor concentration is reduced progressively. The average particle total mass and the degree of branching both increase as the Te precursor concentration is decreased. Without wishing to be bound to any particular theory, these observations can be explained if the overall growth process is considered to occur in two steps: (1) the initial formation of nuclei just after supersaturation and (2) subsequent growth of the nuclei. At low Te concentration, relatively few nuclei form, so that the available monomer per nucleus during the growth phase is relatively high. This leads to fast growth (larger mass at 20 min) and more branching (which is kinetically favored). At high Te concentration, many nuclei form, so the available monomer per nucleus during the growth phase is relatively low. This leads to slow growth (lower mass at 20 min) and less branching.

The quantity of organic stabilizer and the chain length also influence the degree of branching and the morphology of the nanocrystals. Short chain phosphonic acids increase the degree of branching. However, long chain phosphonic acids stabilize the wurtzite structure and therefore decrease the branching. The reduction of the amount of phosphonic acids, while keeping the amount of Te fixed (e.g., at 0.117 mmol), increases the growth rate of the nanocrystal and therefore leads to thinner and longer arms. These sparsely branched, delicate particles tend to align, with arms almost 400 nm long and only 5-6 nm thick forming large, intercalated networks. Their projected solidity is reduced to only 20% (FIG. 1d).

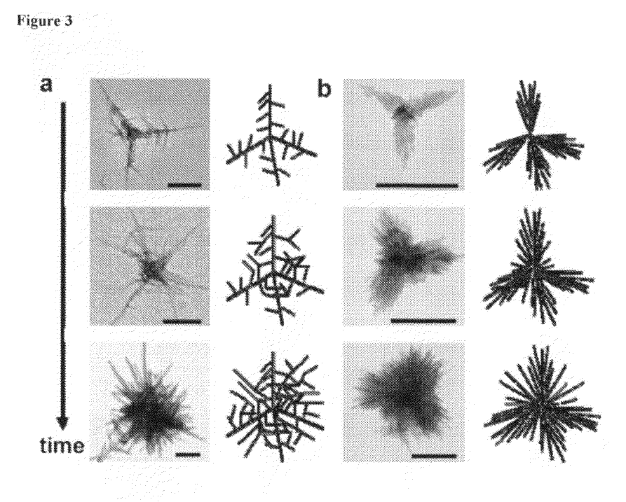

Substitution of selenium (Se) for tellurium Te (FIG. 1e) changes the resulting morphology of the nanocrystals. The original tetrahedral symmetry is clearly visible, with multiple branches projecting outward in groups from a single central tetrahedral branch point (FIG. 3b). The particles display high projected solidity (75%) and a high number of projected tips on the outside (45) despite their relatively small size (200 nm) (FIG. 1).

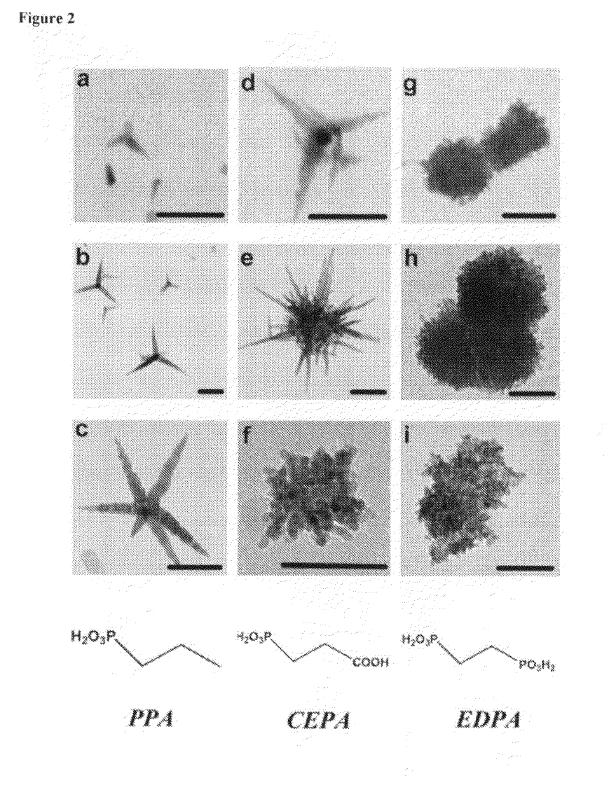

In some embodiments, the choice of specific bifunctional versus monofunctional organic groups also influences the fabrication of hyperbranched nanocrystals. The bifunctional groups can promote branching by creating new nucleation sites adjacent to an existing segment of nanocrystal surface. The local acid concentration is also higher in the vicinity of any given binary surfactant compared to an equal number of independent acid groups on monofunctional surfactants. Changing the ratio of the short chain bifunctional ligand [2-carboxyethylphosphonic acid (CEPA)] to the long chain tetradecylphosphonic acid (TDPA) can influence the branching of the hyperbranched nanoparticles. A ratio of 1:11 of CEPA to TDPA produced high yields of hyperbranched particles. Lower ratios (1:37) (FIG. 2d) lead to very low branching while higher ratios (1:6.5) (FIG. 2f) result in aggregation of spherical particles. The use of a monofunctional phosphonic acid such as propylphosphonic acid (PPA) instead of CEPA does not yield as high a degree of branching (FIGS. 2a-2c), while aggregation of nanocrystals was observed in the presence of even small amounts of a diphosphonic acid like ethyl diphosphonic acid (EDPA) (FIGS. 2g-2i). CEPA combined the features of PPA and EDPA. Low concentrations of CEPA promoted branching, with higher efficiency compared to PPA. High concentrations of CEPA produced extensive aggregation, but with much lower cross-linking efficiency compared to EDPA.

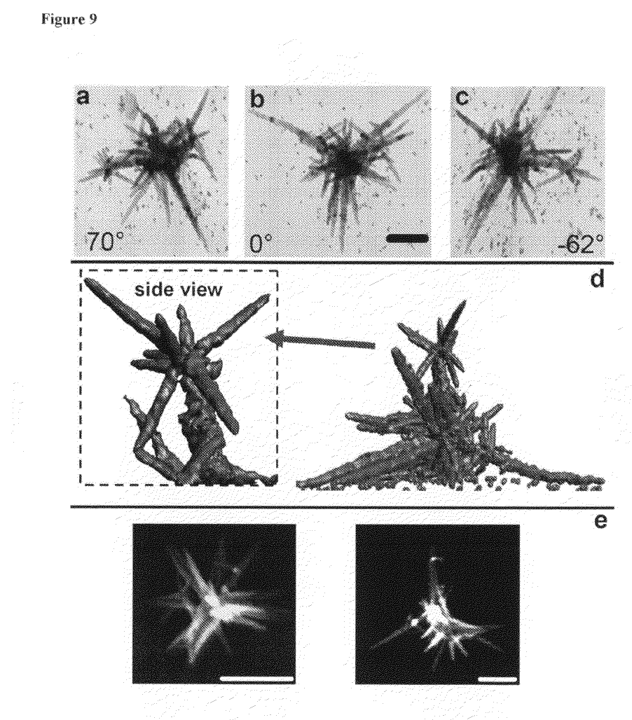

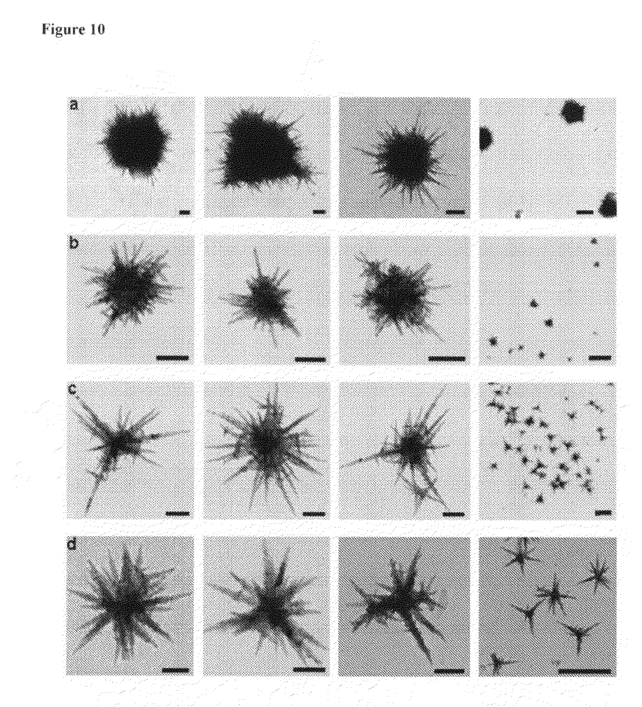

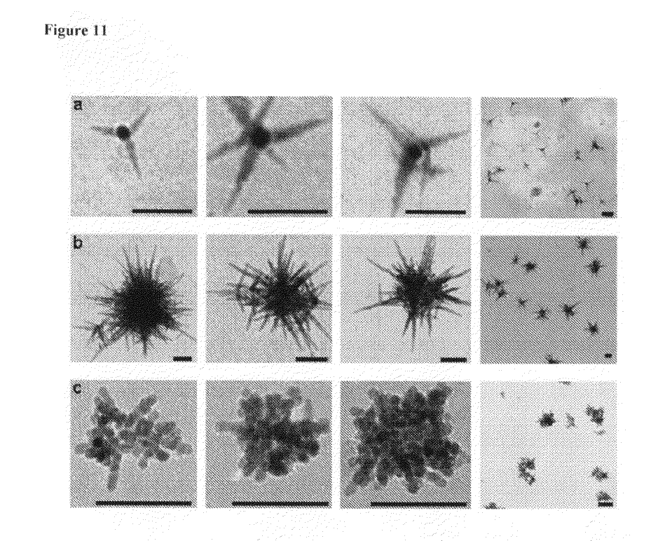

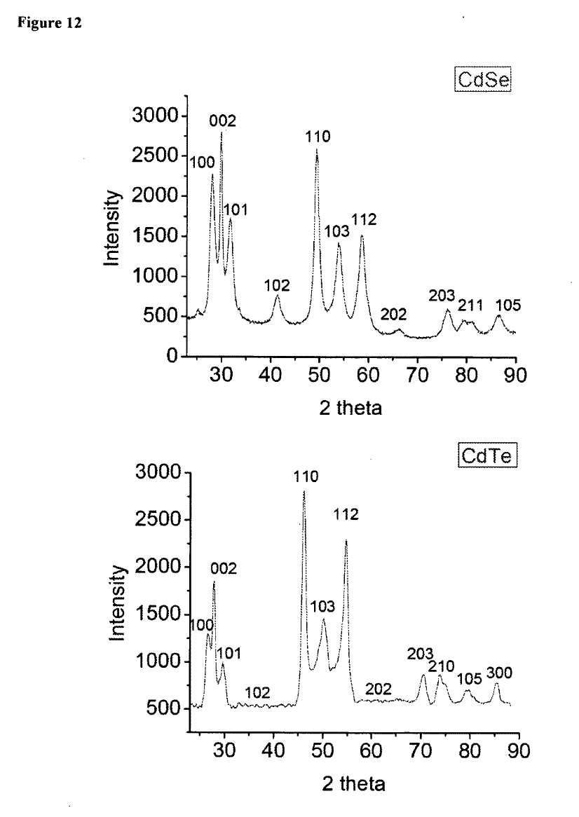

TEM images obtained from aliquots taken at different time intervals from the same CdTe synthesis (using the base conditions defined above) indicates that the particles first grow four arms in a tetrapod-like configuration from which subsequently more and more branches evolve (FIG. 3a). Branches grow both from the center of the particle and from the side of the outward growing arms. Arms forming on the side of an arm point both forward and backward with respect to the growth direction (FIG. 3a, upper left, and FIG. 9). At high branch rates, forward and backward branching at angles other than 109.5° occur. Cubic segments that form at this high growth rate can be frequently twinned, leading to a wide range of possible branching angles.

For TEM tomography, images of the same particle obtained at tilt angles from ±70° in 2 steps were aligned using 5 nm gold particles as markers (FIG. 9d). Examples for three tilt angles are shown in FIGS. 9a-9c. From the resulting stack of images, a full three-dimensional reconstruction is obtained (a side view is shown in FIG. 9d). The particles observed in this way clearly show a main tetrahedral symmetry with one arm pointing straight up (masking it in the usual flat TEM projection). The arms showed contrast changes at different tilt angles as would be expected for single crystalline materials. This suggests that each arm consists of a single crystal, which can be bent sometimes in the case of the arms sitting on the surface. The detailed analysis of branch points shows both forward and backward branching (see images in FIGS. 1-3) as well as points of multiple branching (e.g., FIG. 9d, inset).

### V. Photovoltaic Device

In some embodiments, the present invention provides a photovoltaic device comprising a cathode; an anode; and a photoactive layer comprising a monolayer of the hyperbranched semiconductor nanocrystal particle, wherein the photoactive layer is disposed between the cathode and the anode.

The substrate upon which the monolayer of hyperbranched semiconductor nanocrystal particles of the present invention can be prepared can be any material. Exemplary substrates include, but are not limited to, metal, ceramic, zeolite, glass, plastic, etc. Useful metals include elemental metals, metal oxides and alloys. Metals useful as the surface in the method of the present invention include alkali metals, alkali earth metals, transition metals and post-transition metals. Alkali metals include Li, Na, K, Rb and Cs. Alkaline earth metals include Be, Mg, Ca, Sr and Ba. Transition metals include Sc, Ti, V, Cr, Mn, Fe, Co, Ni, Cu, Zn, Y, Zr, Nb, Mo, Tc, Ru, Rh, Pd, Ag, Cd, La, Hf, Ta, W, Re, Os, Ir, Pt, Au, Hg and Ac. Post-transition metals include Al, Ga, In, Tl, Ge, Sn, Pb, Sb, Bi, and Po. Other metals useful in the present invention include alloys, such as brass. In some embodiments, the substrate is glass.

The substrate of the present invention can be planar or curved, such as on a spherical, elliptical or tubular surface. The substrate can be a bulky flat surface, a thin film with thickness between 5 nm and a 1 mm, or it can be formed from colloidal noble metal particles deposited onto a generic surface. In addition, the substrate can be patterned. When the substrate is patterned, the patterning can be on the micro- or nano-scale.

The device can further comprise an electroactive polymer that is mixed with the monolayer of hyperbranched semiconductor nanocrystal particles. The electroactive polymer of the present invention can be any conductive polymer (e.g., a conjugated polymer). In some embodiments, the electroactive polymer can be poly(acetylene)s, poly(pyrrole)s, poly(thiophene)s, poly(aniline)s, poly(fluorene)s, poly(3-alkylthiophene)s, polytetrathiafulvalenes, polynaphthalenes, poly(p-phenylene sulfide), and poly(para-phenylene vinylene)s, among others. In other embodiments, the electroactive polymer is a poly(3-alkylthiophene). In still other embodiments, the electroactive polymer is poly(3-hexylthiophene-2,5-diyl).

The electroactive polymer of the present invention can also be doped. Dopants useful in the electroactive polymer of present invention include, but are not limited to, metals and metal ions, semi-metals, alloys, charge-transfer agents and dyes. Metals that are useful in the present invention include the alkali metals, alkali earth metals, transition metals and post-transition metals. Alkali metals include Li, Na, K, Rb and Cs. Alkaline earth metals include Be, Mg, Ca, Sr and Ba. Transition metals include Sc, Ti, V, Cr, Mn, Fe, Co, Ni, Cu, Zn, Y, Zr, Nb, Mo, Tc, Ru, Rh, Pd, Ag, Cd, La, Hf, Ta, W, Re, Os, Ir, Pt, Au, Hg and Ac. Post-transition metals include Al, Ga, In, Tl, Ge, Sn, Pb, Sb, Bi, and Po. One of skill in the art will appreciate that the metals described above can each adopt several different oxidation states, all of which are useful in the present invention. In some instances, the most stable oxidation state is formed, but other oxidation states are useful in the present invention.

Dyes useful as dopants in the present invention can be any dye. Exemplary dyes useful in the present invention include, but are not limited to, alexa, cyanine, rhodamine, fluorescein, Oregon green, Texas red, coumarins, pyrenes, Bodipy, cascade blue and lucifer yellow. One of skill in the art will appreciate that other dyes are useful in the present invention.

The monolayer of hyperbranched semiconductor nanocrystal particle can be prepared using any known method. In some embodiments, the hyperbranched semiconductor nanocrystal particles are mixed with the electroactive polymer and deposited onto the substrate via spin-coating. In other embodiments, the hyperbranched semiconductor nanocrystal particles are covalently linked to the substrate surface using bifunctional linkers such as alkyldithiols. One of skill in the art will appreciate that other methods of depositing the hyperbranched semiconductor nanocrystal particles on the substrate surface are useful in the present invention.

In some embodiments, the substrate is coated with an anode or cathode material prior to deposition of the monolayer of hyperbranched semiconductor nanocrystal particles.

The electrodes (anode and cathode) of the photovoltaic device of the present invention can comprise any material. Suitable electrode materials include, but are not limited to, metals, metal oxides, alloys, ceramics and conducting polymers. In some embodiments, electrode materials include indium tin oxide (ITO) and aluminum. One of skill in the art will appreciate that other electrode materials are useful in the present invention.

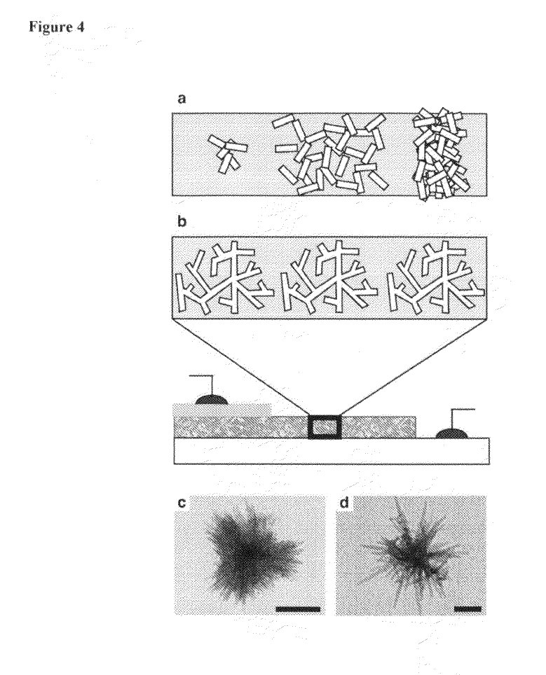

As illustrated in FIG. 4, hyperbranched nanocrystals allow the creation of a new class of hybrid solar cells, whose unique architecture affords several advantages over conventional approaches. The branching structure of the nanocrystals controls the dispersion of the inorganic phase in the polymer matrix, thus ensuring a large, distributed surface area for charge separation. Defects such as islands and aggregates, which are detrimental to the performance of conventional hybrid cells, are eliminated in hyperbranched particle composites, where blend morphology is dictated entirely by the 3-D structure of the hyperbranched nanocrystal. Moreover, as shown in FIG. 4b, hyperbranched particles span the entire device thickness and thus contain a built-in percolation pathway for hopping-free transport of electrons to the anode, thereby enhancing electron transport and eliminating the need for strict control of particle dispersion within the matrix. With decreased sensitivity to variations in processing, a simple monolayer of such nanocrystals in a polymer matrix provides a controlled, ordered, and well-defined bulk heterojunction with the dispersion and percolation required for charge separation and transport.

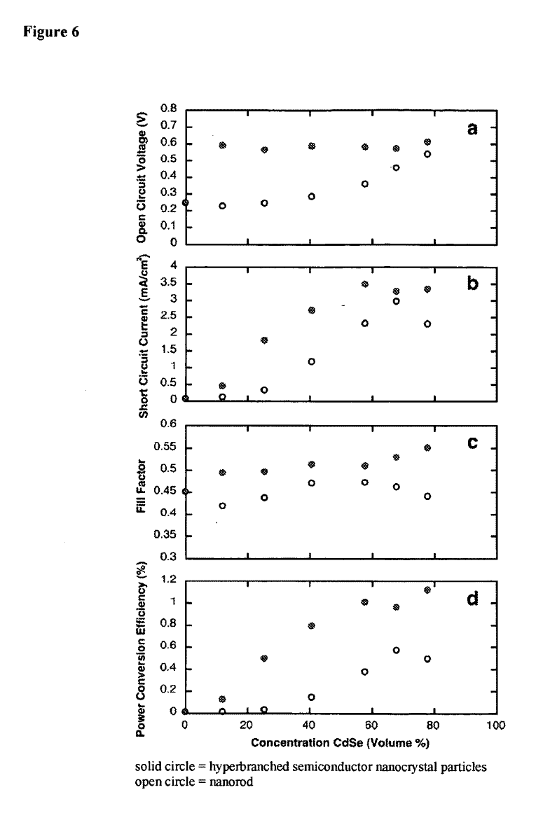

Without wishing to be bound to any particular theory, a simple model of the hyperbranched nanocrystal solar cell can explain the results above. Each hyperbranched particle embedded within the P3HT matrix represents a very small (roughly 150 nm×150 nm×150 nm), yet fully functional hybrid solar cell. The three-dimensional volume of the hyperbranched semiconductor nanocrystal particles minimizes intercalation of the particles and allows each particle to be in contact with both the anode and the cathode. Thus, each hyperbranched semiconductor nanocrystal particle is itself a photovoltaic device such that a monolayer of hyperbranched semiconductor nanocrystal particles is an array of nanoscale photovoltaic devices. The independent single-particle cells are then effectively connected in parallel to create the full device. Data from hyperbranched particle cells support this picture of a simple parallel circuit: voltage remains constant with the addition of hyperbranched particles to the matrix, while the current is additive (FIGS. 6A and 6B).

In some embodiments, the photovoltaic device of the present invention comprises a monolayer of hyperbranched semiconductor nanocrystal particles such that each hyperbranched semiconductor nanocrystal particle is in contact with both the anode and the cathode. Thus, each hyperbranched semiconductor nanocrystal particle acts as an individual photovoltaic device. Accordingly, the monolayer of hyperbranched semiconductor nanocrystal particles acts as a nanoscale array of photovoltaic devices wherein each photovoltaic device is a single hyperbranched semiconductor nanocrystal particle.

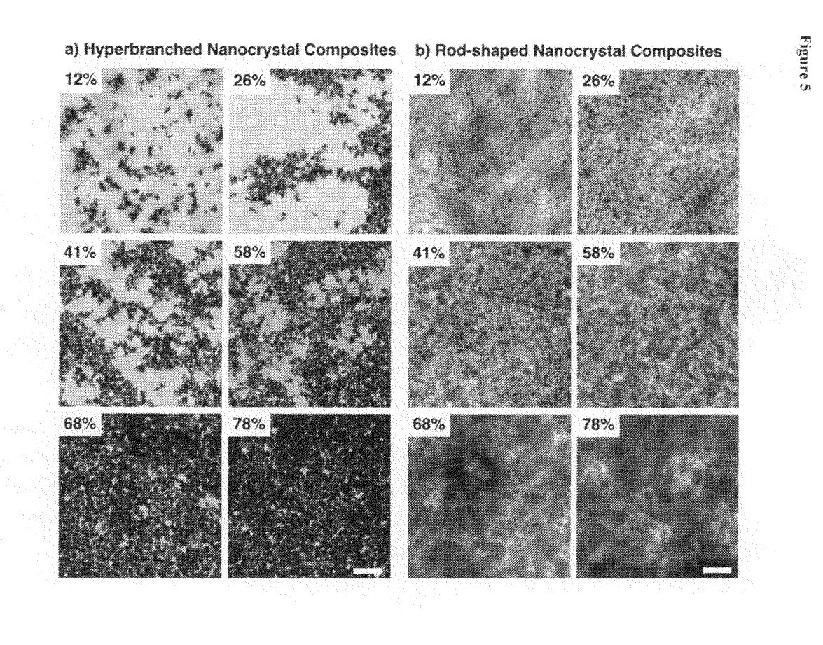

Based on this model, a well-defined, closed-packed monolayer of hyperbranched nanocrystals yields excellent performance. Increased CdSe loading in hyperbranched particle cells yields initially a nearly linear enhancement of power conversion efficiency, but this improvement saturates at high loading concentrations (FIG. 6d). Juxtaposed with the TEM images in FIG. 5b, the device data show that cell performance levels off approximately when the hyperbranched particles form a complete monolayer within the P3HT matrix. Beyond a monolayer, additional hyperbranched particles are either excluded from integration into the matrix or, if incorporated, do not appear to have a dramatic effect on performance. The cells presented here seem to be limited in performance by the tight branching in these prototype hyperbranched particles. Thus, the optimization of hyperbranched particle cells seems to be simple, well defined, clearly characterized, and easily attained.

Hyperbranched nanocrystal devices outperform those made from nanorods in every parameter across all measured loading concentrations. Optimal performance from a nanorod cell requires hitting a ‘sweet spot’ in blend morphology, a difficult task given their erratic dependence on processing conditions. In contrast, the simple composite architecture of hyperbranched particle cells affords a decreased sensitivity to small variations in loading concentration and processing. This is evident in a comparison of fill factor (FF) parameter between the two classes of devices. FF values, which reflect diode ideality and overall cell quality, are not only higher but much more constant in hyperbranched particle cells than nanorod cells across the range of loading ratios (FIG. 6c).

### VI. Examples

Materials. Cadmium oxide (CdO, 99.99+%), Selenium (Se, 99.999% 100 mesh), tri-n-octylphosphine oxide (TOPO, 99%), and 2-Carboxyethylphosphonic acid (CEPA, 94%) were purchased from Aldrich. n-Tetradecylphosphonic acid (TDPA, 99%) and n-Hexylphosphonic acid (HPA, 99%) were purchased from PolyCarbon Industries, Inc. Trioctylphosphine (TOP, 97%) was purchased from Strem Chemicals. Regioregular electronics grade poly(3-hexylthiophene-2,5-diyl) (P3HT) was purchased from Reike Specialty Polymers. Tellurium (Te) shots and 1,2-ethylene diphosphonic acid (EDPA) were purchased from Alfa Aesar and Selenium (Se) powder 99.9% from Aldrich. All solvents used were anhydrous, purchased from Aldrich, and used without any further purification.

### Example 1

### Preparation of Hyperbranched Semiconductor Nanocrystal Particles

Basic protocol for synthesis of hyperbranched CdTe or CdSe particles. CdO (0.15 g, 1.1 mmol) was added in a mixture of TDPA (1 g, 3.59 mmole), CEPA (0.05 g, 0.32 mmole), and TOPO (3 g, 7.7 mmole), heated at 150° C. and kept under vacuum for 30 min to remove small amounts of water. Then the temperature was set at 335° C. and the brownish mixture was left under argon for 1 hour. This step resulted in a colorless solution due to the decomposition of the CdO and the formation of a Cd/phosphonic acid complex. TOP (1.2 g, 3.23 mmole) was injected and the temperature was adjusted to 335° C. Te and Se stock solutions were prepared by dissolving Te or Se in TOP (5%, 3.1% w/w, respectively). The mixture of Te:TOP (0.30 g, 0.117 mmole) or Se:TOP (0.30 g, 0.117 mmole) was injected into the hot reaction solution and the temperature was set to 330° C. (For all experiments the volume of the injected Te precursor was kept constant.) The color changed from colorless to brownish within 4-5 minutes indicating the formation of nanocrystals. The solution was left at 330° C. for another 20 min before it was cooled down to 100° C. Toluene (3 ml) was injected and the particles precipitated with isopropanol. To purify the particles from the reactants, the solution was centrifuged and the sediment re-dissolved in toluene. After a second precipitation with isopropanol, the sediment was re-dissolved in chloroform and kept for further analysis. Some particles settle down over time, but were easily re-suspended by sonication. The same procedure was followed to all the experiments by varying the tellurium/selenium or phosphonic acids concentration.

Synthesis of CdSe Hyperbranched Particles. All manipulations were performed using standard air-free techniques. In a typical synthesis of CdSe hyperbranched particles, a mixture of 1.00 g TDPA, 50 mg CEPA, 3.00 g TOPO, and 155 mg CdO was degassed at 120° C. for 60 minutes in a 25 ml three-neck flask connected to a Liebig condenser. It was heated slowly under Ar until the CdO decomposed and the solution turned clear and colorless. Next, 1.2 g of TOP were added, and the temperature was further raised to 315° C. A stock solution of Se dissolved in TOP at 3.1% Se by weight was previously prepared, and 0.3 g were rapidly injected to the vigorously stirring precursors and particles were allowed to grow for 15 minutes before the heat was removed to stop the reaction. After cooling the solution to 70° C., 3-4 ml anhydrous toluene were added to the flask, and the dispersion was transferred to an Ar drybox. The minimum amount of anhydrous isopropanol required to precipitate the nanocrystals was added to the dispersion. This prevented potential co-precipitation of the Cd-phosphonate complex. After centrifuging and removing the supernatant, the precipitate was re-dissolved in pure toluene.

### Example 2

### Photovoltaic Cell with Hyperbranched Semiconductor Nanocrystal Particles

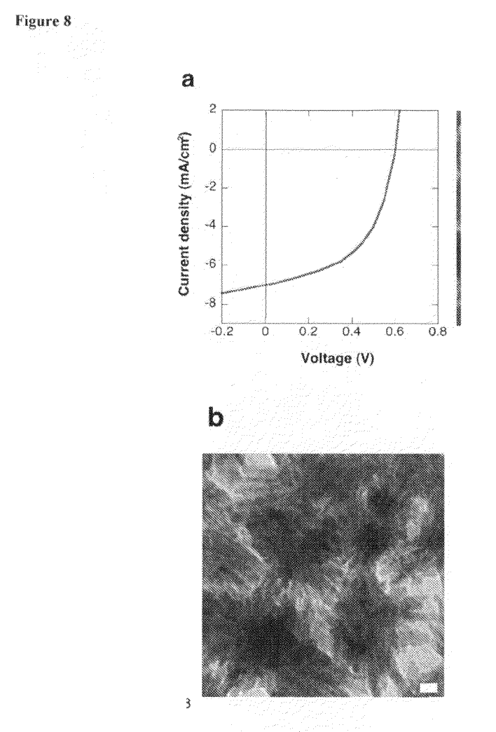

Device Fabrication. All manipulations were performed using standard air-free techniques. To create cells based on hyperbranched nanocrystals, particles synthesized as described above were washed 2× by dissolution in toluene and subsequent precipitation with isopropanol, then suspended in 20 mL pyridine and stirred under reflux overnight for comprehensive ligand exchange. After reflux, the nanocrystals were precipitated with hexane, washed with toluene, and re-suspended in approximately 500 μL chloroform. These highly concentrated suspensions were ultrasonicated for ca. 10 minutes and combined with solutions of P3HT in pure chloroform. The blends were then spin-cast at 1500 rpm onto glass substrates coated with 150 nm ITO (Thin Film Devices Inc., resistivity 20 ohms/sq), and annealed on a hot plate at 120° C. for 60 minutes. Finally, samples were held at ca. 10⁻ torr overnight, after which aluminum top electrodes were deposited by thermal evaporation through a shadow mask, resulting in individual devices with 0.03 cm² nominal area. The device shown in FIG. 8 was made using P3HT dissolved in trichlorobenzene rather than chloroform, and was annealed at 150° C. for 60 minutes after deposition of the top contacts.

Device Characterization. Simulated AM1.5G illumination was obtained with a Spectra Physics Oriel 300 W Solar Simulator with AM1.5G filter set. The integrated intensity was set to 100 mW/cm² using a thermopile radiant power meter (Spectra Physics Oriel, model 70260) with fused silica window, and verified with a Hamamatsu S1787-04 diode. Intensity was controlled to be constant throughout measurements with a digital exposure controller (Spectra Physics Oriel, model 68950). Spectral response curves were measured at low intensity (<0.1 mW/cm2), using monochromated light from a tungsten source.

FIG. 8a presents current-voltage characteristics for a hyperbranched nanocrystal cell with a one-sun AM1.5G efficiency of 2.2%, achieved via optimization of the deposition solvents and the annealing conditions FIG. 8b shows a high-magnification TEM image of the composite used to make this device. Close examination of the blend micrograph reveals that nearly optimal 5 nm-20 nm P3HT domains are created between adjacent particles as a result of their urchin-like branching structure.

### Example 3

### Comparison of Hyperbranched Nanocrystal Photovoltaic Cell and Nanorod Photovoltaic Cell

FIG. 4 presents transmission electron micrographs of typical hyperbranched nanocrystals of cadmium selenide (CdSe) (FIG. 4c) and cadmium telluride (CdTe) (FIG. 4d). In one arrangement, hyperbranched CdSe crystals as shown in FIG. 4c were integrated into a matrix of poly(3-hexylthiophene) (P3HT) to produce hybrid solar cells. The conventional CdSe/P3HT donor-acceptor pair is well understood, and thus serves as a model system to understand behavioral changes due to the use of hyperbranched nanocrystals.

In order to explore the advantages of hyperbranched particles and the importance of their pre-formed percolation networks, a controlled comparison was made between nanorod-polymer solar cells and hyperbranched nanocrystal-polymer solar cells, each having the same percent of inorganic component. Transmission electron micrographs of these nanocomposite films are shown for six different concentrations of CdSe in FIG. 5. The images elucidate several differences. With increased loading, nanorods incorporate into the polymer matrix in a random manner, barely occupying some regions while forming large, disordered aggregates in others (FIG. 5b). In contrast, the hyperbranched particles populate the polymer matrix more deterministically (FIG. 5a). Similar in dimension to the thickness of the film, they are added contiguously, gradually approaching a well-defined monolayer with increased loading. Moreover, the nominally isotropic shape of the hyperbranched particles eliminates disorder stemming from differences in rotational orientation of the particles. Like organic dendrimers, hyperbranched nanocrystals are more easily processed from fine suspensions without aggregating. Composites based on 3-D particles can therefore be spin-cast from a single solvent, and are not prone to the large-scale aggregation characteristic of nanorod blends, which must be spun from a 2-solvent solution. Moreover, processing from a single solvent eliminates the long-range thickness variations of the P3HT matrix. Finally, spin-casting the final blend from pure chloroform, a good solvent for P3HT, can allow for optimal crystallization of polymer domains in the final film.

The differences in morphology and dispersion between rod and hyperbranched nanocrystal composites manifest themselves in solar cells based on these separate systems. Solar cells based on the composites illustrated in FIGS. 5a and 5b were prepared. FIG. 6 shows a summary of operating characteristics for these cells, measured under simulated one-sun AM1.5 global illumination. Data points represent highest measured values from a set of 8 regions of each substrate. Cells based on nanorods (open circles) behave as previously observed. The nominal open circuit voltage (V_{oc}) of a P3HT-only device is measured at low nanorod loading, and is preserved until a threshold representing the formation of CdSe percolation networks across the device is reached (FIG. 6a). At this point, the V_{oc} rises to approach that of the complete heterojunction. A similar trend is observed in the short circuit current (I_{sc}) (FIG. 6b). Almost no carriers can be extracted from the device at low loading. Only when percolation networks begin to form in the nanocrystal phase can charge be extracted from the film.

Cells based on hyperbranched particles (closed circles) exhibit characteristically different behavior. With incorporation of only a small number of nanocrystals, the V_{oc} rises immediately to its full value of approximately 0.6 V, and remains constant with increased loading. That the device behaves like a complete heterojunction with so few particles is easily understood; each hyperbranched particle contains a pre-formed percolation path and can thus contribute fully to photovoltaic conversion. The absence of a threshold loading density is also evident in the I_{sc} of hyperbranched cells, as well as in the final power conversion efficiency (η) (FIG. 6d). In contrast with nanorod devices, cells based on hyperbranched particles show a near-linear rise in both I_{sc} and η with increased loading of CdSe. This, too, is consistent with the idea that a single incorporated hyperbranched particle can contribute independently to the cell's output by virtue of its unique morphology.

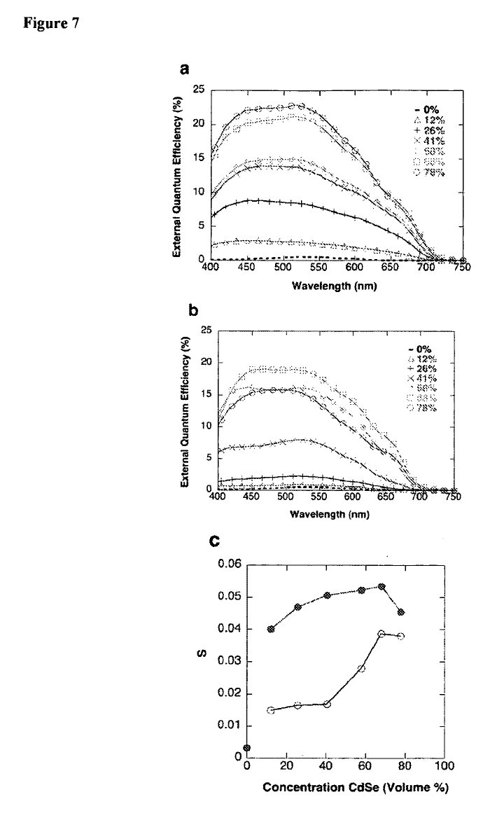

A spectral analysis of the current output in these cells was performed. FIG. 7 presents photocurrent spectra from the rod (FIG. 7a) and hyperbranched particle (FIG. 7b) devices at various concentrations as discussed above. The spectral response of pure P3HT, included for reference, is consistent with a measured absorption edge of 660 nm, beyond which the polymer is unable to absorb incident radiation. Any response from blend devices at wavelengths greater than 660 nm must therefore be the direct result of absorption events in the nanocrystalline phase. Thus, the relative current contribution from this low-energy portion of a given spectrum directly reflects the degree to which carriers created in the CdSe are extracted from the device.

A shape parameter, S, is defined to be the integrated current from 660 nm-750 nm divided by the fully integrated photocurrent of the cell.

$$S = \frac{{\int }_{660 nm}^{750 nm} EQE ( λ ) \cdot d λ}{{\int }_{35 nm}^{750 nm} EQE ( λ ) \cdot d λ}$$

Simply put, S is a measure of the cell's ability to extract charges created in the nanocrystals and reflects the contribution to the photocurrent exclusively as a result of CdSe absorption events. A plot of S vs. loading density for nanorod (FIG. 7c, open circles) and hyperbranched (closed circles) particle solar cells elucidates the self-contained percolation structure of hyperbranched nanocrystals. The concentration of CdSe reaches a threshold before charges are extracted from nanorod CdSe. In contrast, hyperbranched CdSe particles seem to contribute independently to current generation, even at low concentrations.

Although the foregoing invention has been described in some detail by way of illustration and example for purposes of clarity of understanding, one of skill in the art will appreciate that certain changes and modifications may be practiced within the scope of the appended claims. In addition, each reference provided herein is incorporated by reference in its entirety to the same extent as if each reference was individually incorporated by reference.

What is claimed is:

1. A hyperbranched semiconductor nanocrystal particle comprising:
a first arm, wherein the first arm comprises an intermediate portion and opposing terminal portions; and
a second arm, extending from the intermediate portion of the first arm.

2. The hyperbranched semiconductor nanocrystal particle of claim 1, wherein one of the terminal portions of the first arm is a core.

3. The hyperbranched semiconductor nanocrystal particle of claim 2, further comprising a plurality of arms each comprising an intermediate portion and opposing terminal portions, wherein each arm extends from either the intermediate portion of another arm or the core of the first arm.

4. The hyperbranched semiconductor nanocrystal particle of claim 1, further comprising at least 10 arms.

5. The hyperbranched semiconductor nanocrystal particle of claim 1, further comprising at least 6 branch points.

6. The hyperbranched semiconductor nanocrystal particle of claim 1, comprising a Group I-VII semiconductor, a Group II-VI semiconductor, a Group II-V semiconductor, a Group III-V semiconductor, a Group IV semiconductor, a Group IV-VI semiconductor, a Group V-VI semiconductor, a metal or a material exhibiting polytypism.

7. The hyperbranched semiconductor nanocrystal particle of claim 1, comprising a Group II-VI semiconductor.

8. The hyperbranched semiconductor nanocrystal particle of claim 1, comprising a Group II-VI semiconductor selected from the group consisting of CdSe, CdTe, CdS, ZnO, ZnSe, ZnS, ZnTe, CdZnTe, HgCdTe, HgZnTe and HgZnSe.

9. The hyperbranched semiconductor nanocrystal particle of claim 1, comprising a Group II-VI semiconductor selected from the group consisting of CdSe and CdTe.

10. A hyperbranched semiconductor nanocrystal particle comprising:
at least five primary arms extending from a core, wherein each primary arm comprises an intermediate portion and opposing terminal portions, wherein the core comprises one terminal portion of each of the primary arms.

11. The hyperbranched semiconductor nanocrystal particle of claim 10, further comprising secondary arms, wherein each secondary arm comprises an intermediate portion and opposing terminal portions, wherein each secondary arm extends from the intermediate portion of one of the primary arms or from the intermediate portion of another of the secondary arms.

12. A method comprising:
contacting a first semiconductor precursor, a second semiconductor precursor and a surfactant mixture comprising a bifunctional surfactant, thereby preparing a hyperbranched semiconductor nanocrystal particle.

13. The method of claim 12, wherein the surfactant mixture further comprises a monofunctional surfactant.

14. The method of claim 13, wherein each monofunctional surfactant is a member selected from the group consisting of a phosphine, a phosphonic acid, a phosphinic acid, a phosphine oxide, an amine and a fatty acid.

15. The method of claim 12, wherein each monofunctional surfactant is a member selected from the group consisting of propylphosphonic acid, n-tetradecylphosphonic acid (TDPA), tri-n-octyl phosphine oxide and tri-n-octylphosphine.

16. The method of claim 12, wherein each bifunctional surfactant comprises two semiconductor binding groups each independently selected from the group consisting of a carboxylic acid group, an amine group, a phosphonic acid group, a phosphine group and a phosphine oxide group.

17. The method of claim 16, wherein each bifunctional surfactant is a member selected from the group consisting of 2-carboxyethylphosphonic acid (CEPA) and 1,2-ethylene diphosphonic acid (EDPA).

18. The method of claim 17, wherein the bifunctional surfactant is CEPA.

19. The method of claim 14, wherein the ratio of monofunctional surfactant to bifunctional surfactant is from about 1:1 (mol/mol) to about 50:1 (mol/mol).

20. The method of claim 19, wherein the ratio of monofunctional surfactant to bifunctional surfactant is from about 5:1 (mol/mol) to about 20:1 (mol/mol).

21. The method of claim 19, wherein the ratio of monofunctional surfactant to bifunctional surfactant is about 11:1 (mol/mol).

22. The method of claim 19, wherein the monofunctional surfactant comprises n-tetradecylphosphonic acid (TDPA) and the bifunctional surfactant is 2-carboxyethylphosphonic acid (CEPA), and the ratio of TDPA:CEPA is about 11:1 (mol/mol).

23. The method of claim 13, wherein the surfactant mixture comprises n-tetradecylphosphonic acid, tri-n-octyl phosphine oxide, tri-n-octylphosphine and 2-carboxyethylphosphonic acid.

24. The method of claim 12, wherein the first semiconductor precursor is in a first surfactant mixture comprising n-tetradecylphosphonic acid, tri-n-octyl phosphine oxide, tri-n-octylphosphine and 2-carboxyethylphosphonic acid.

25. A photovoltaic device comprising:
a cathode;
an anode; and
a photoactive layer comprising a monolayer of hyperbranched semiconductor nanocrystal particles, wherein the photoactive layer is disposed between the cathode and the anode.
